(19) United States
(12) Patent Application Publication
(10) Pub. No.: US 2025/0364802 A1
(43) Pub. Date: Nov. 27, 2025

(54) END EFFECTOR WITH INTEGRATED FEEDBACK PROTECTION DEVICE, AND METHOD

(71) Applicant: SCHUNK SE & Co. KG Spanntechnik Greiftechnik Automatisierungstechnik, Lauffen am Neckar (DE)

(72) Inventors: Thilo Pirner, Oberstenfeld (DE); Johannes Wöhr, Güglingen (DE); Thomas Stalter, Knittlingen (DE); Steffen Mittendorff, Heilbronn (DE)

(21) Appl. No.: 19/297,528

(22) Filed: Aug. 12, 2025

(30) Foreign Application Priority Data
Aug. 13, 2013 (DE) 10 2024 123 031.2

(51) Int. Cl. H02H 7/09; B25J 9/12; B25J 15/02; B25J 19/00

(52) U.S. Cl. CPC H02H 7/09; B25J 9/12; B25J 15/02; B25J 19/0004

(57) ABSTRACT

An end effector for arrangement on a handling apparatus comprises an effector element movable by an electric drive, a feedback protection device integrated in the end effector for receiving and/or converting a feedback voltage during braking of the electric drive, and a control device for controlling the feedback protection device.

### TECHNICAL FIELD

This disclosure relates to an end effector and to methods for operating an end effector.

### BACKGROUND

In end effectors with electric drives, the drive acts as a generator during braking, with the rotor inducing an electrical voltage in the stator windings. The induced voltage can lead to malfunction or destruction of power and control electronics in an end effector. External energy sources, such as power supply units that supply the end effector with energy, can also enter an error mode and shut down if the feedback voltage is too high. This leads to problems in the process and can also pose a safety risk.

### SUMMARY

This disclosure provides an end effector system that ensures reliable operation under braking conditions by integrating a feedback protection device to manage reverse currents, thereby protecting internal and external electronics.

In aspects of this disclosure, the end effector comprises a main housing; at least one movable effector element, in particular movably mounted in or on the main housing; an electric drive, in particular arranged in or on the main housing, for driving the at least one effector element; a feedback protection device integrated in the end effector, in particular arranged in the main housing, for receiving and/or converting a feedback voltage during braking of the electric drive; and a control device, in particular arranged in or on the main housing, for controlling the feedback protection device.

The energy stored in the electric drive by braking can result in a feedback voltage that is converted into heat. Consequently, the power and control electronics of the end effector as well as integrated or external energy sources can be protected from excessive currents or voltages, in particular the feedback voltage. This eliminates the need for a separate fuse on a customer-side power supply unit.

In one embodiment, a gripper is provided for arrangement on a handling device, wherein the gripper comprises a base housing; at least one effector element, in particular a gripper jaw, movably mounted in or on the base housing and movable by an electric drive; a feedback protection device arranged in the base housing for receiving and/or converting a feedback voltage during the braking process of the electric drive; and a control device for controlling the feedback protection device, which is configured to control the feedback protection device as a function of an average value of an actual voltage and an activation limit voltage and/or deactivation limit voltage, the activation limit voltage and/or the deactivation limit voltage being determined from the actual voltage and an activation offset and/or a deactivation offset.

The handling device can be configured as a robot or gantry. The end effector can be configured as a gripper, in particular a mechatronic gripper. In some aspects of this disclosure, the gripper has a base housing and at least two gripper jaws that are guided and displaceable in the base housing. The gripper jaws are displaceable between an open position and a closed position. The gripper has a gripper holder for holding an object, whereby the gripper holder is limited by the base housing and/or the gripper jaws. The base housing has a guide recess for guiding the gripper jaws. The gripper can have two gripper jaws that can be moved along an axis. Alternatively, the gripper can have three or more gripper jaws (centric gripper). In some aspects of the disclosure, the gripper is configured as an internal or external gripper. The feedback protection device can be arranged in the base housing of the gripper, which has the guide recess and guides the gripper jaws.

Due to the limited size of the end effector, in particular the main housing, the end effector is configured to be battery-free, e.g., without a battery. Storing the braking energy is therefore neither practical nor possible in the context of a compact end effector.

The electric drive is configured as an electric motor, in particular an internal rotor motor or an external rotor motor.

In aspects of this disclosure, the feedback protection device can have at least one load resistor, in particular two, three or four load resistors, for converting the feedback voltage into heat. The braking energy is converted into thermal energy in at least one load resistor. The thermal energy is released to the environment via the main housing.

In aspects of this disclosure, the feedback protection device has a switch for activating and deactivating the feedback protection device. The switch is configured as a field-effect transistor. In the deactivation state, no energy is converted into thermal energy to drive the end effector. In the activation state, the braking energy introduced into the system during braking is, inter alia, converted into thermal energy. The feedback protection device can be used specifically when, for example, a feedback voltage is coupled into the end effector. In the deactivation state, the energy source, in particular the power supply unit, can independently regulate the appropriate voltage in the end effector.

The end effector can have an electrical interface for connection to an electrical energy source for supplying energy to the electric drive. The electrical energy source can be, for example, an external power supply unit.

The end effector can have a supply line that electrically connects the electrical interface to the electric drive.

In aspects of this disclosure, the feedback protection device is connected to a supply line that electrically connects the electrical interface and the electric drive. In aspects of this disclosure, the at least one load resistor is electrically connected in parallel with the supply line.

The supply line can in particular be formed separately from a first circuit board and/or a second circuit board. Alternatively, the supply line can also be arranged on and/or at and/or in a first circuit board and/or a second circuit board. In aspects of this disclosure, the power supply unit is arranged in the gripper and/or on the first circuit board and/or the second circuit board.

In aspects of this disclosure, the feedback protection device is designed such that the switch, in an activation state, electrically connects the at least one load resistor to the supply line and/or, in a deactivation state, electrically disconnects the at least one load resistor from the supply line. A current flows from the supply line to the feedback protection device only when the switch is in the activation state.

In aspects of this disclosure, the end effector has a voltage measuring device for measuring a first variable that characterizes an actual voltage applied to the supply line, in particular the actual voltage itself. The voltage measuring device can measure the first variable cyclically at discrete time intervals or continuously.

In aspects of this disclosure, the feedback protection device, in particular the at least one load resistor and/or the switch and/or a contact point for connecting the load resistor to the supply line, is arranged on a common first circuit board.

In aspects of this disclosure, the control device is designed to control the electric drive and to activate and deactivate the feedback protection device. The control device may comprise a microcontroller with firmware. The microcontroller can be designed in particular as an integrated circuit on the second circuit board. The control device can specifically activate and deactivate the feedback protection device depending on the conditions described above.

The control device is arranged on a second circuit board that is formed separately from the first circuit board. On the first circuit board, significant heat generation and/or electromagnetic interference due to high currents occur, which can negatively affect the components on the second circuit board. This phenomenon can be reduced by forming the circuit boards separately. In aspects of this disclosure, the first circuit board and the second circuit board are spaced apart from one another. Alternatively, in aspects of this disclosure, the first circuit board and the second circuit board are formed by a common circuit board and/or are fulfilled by a common circuit board. In this case, the feedback protection device, in particular the at least one load resistor and/or the switch, can be arranged on a common circuit board together with the control device, in particular with the microcontroller and/or components of a power electronics system.

In aspects of this disclosure, control device is configured such that it activates or deactivates the feedback protection device depending on an actual voltage applied to the supply line and/or an operating state of the end effector, in particular a motor operating state and a generator operating state. The feedback protection device can be specifically activated and deactivated by the control device.

In aspects of this disclosure, the control device is configured such that it activates the feedback protection device when an actual voltage applied to the supply line exceeds an activation threshold voltage and in particular when the end effector is, predominantly, in a generator operating state. The operating ranges can be stored in the end effector in which the electrical components are not damaged.

In aspects of this disclosure, the control device is configured such that it deactivates the feedback protection device when an actual voltage applied to the supply line falls below a deactivation threshold voltage. The feedback protection device is switched off so that there is no conflict with a power supply unit that also regulates the voltage. In aspects of this disclosure, the control device is configured such that it deactivates the feedback protection device when, additionally or alternatively, the end effector is, predominantly, in a motor operating state. Accordingly, the feedback protection device is deactivated when there are no more feedback voltages.

In aspects of this disclosure, the feedback protection device has a temperature-dependent protective circuit. The protective circuit is configured such that it switches to an interruption state when a threshold temperature is reached or exceeded. This can be done mechanically by blowing the protective circuit in the form of a fuse and/or by interrupting the protective circuit in the software, so that no energy is conducted to the load resistor.

In aspects of this disclosure, a method comprises the following steps:
a) measuring an actual voltage applied to a supply line of the end effector,
b) if the actual voltage exceeds an activation threshold voltage, activating a feedback protection device integrated in the end effector, wherein the activation limit voltage is determined from the actual voltage and an activation offset, and/or
c) if the actual voltage falls below a deactivation threshold voltage, deactivating the feedback protection device integrated in the end effector, wherein the deactivation limit voltage is determined from the actual voltage and an deactivation offset.

The activation threshold voltage ensures that the feedback protection device only intervenes when the voltage in the system is actually too high.

In aspects of this disclosure, the method is designed as a computer-implemented method.

In aspects of this disclosure, the method comprises the following step before step b):
a1) detecting an operating state of the end effector, in particular a generator operating state or a motor operating state.

In aspects of this disclosure, the feedback protection device according to step b) is activated only when the actual voltage exceeds the activation threshold voltage and also when the end effector is in a generator operating state.

In generator mode, the electric drive acts as a generator when driven by a load and feeds electrical energy back into the system. A controller cascade provided in the end effector, in particular in the control unit, detects whether the electric drive is being used as a drive or as a generator.

In aspects of this disclosure, the feedback protection device according to step c) is deactivated only when the actual voltage falls below a deactivation threshold voltage and/or when the end effector is in a motor operating state.

In aspects of this disclosure, the measured actual voltage is filtered to determine a mean value of the actual voltage, in particular by means of an infinite impulse response (IIR) filter. Since an IIR filter takes into account both current and past values, it effectively filters out noise signals. The use of an IIR filter allows strong filtering to eliminate high-frequency noise components and obtain a smooth, stabilized mean value of the actual voltage.

In aspects of this disclosure, the activation threshold voltage is determined by adding an activation offset to the mean value. In aspects of this disclosure, the deactivation threshold voltage is determined by adding a deactivation offset to the mean value. In this case, these are relative deactivation thresholds or activation thresholds. This allows for better adaptation to variable operating conditions, as they are related to the current states of the system. Relative activation thresholds are independent of absolute values. This means that changes in the supply voltage or other global system parameters do not directly affect the thresholds. In systems with different configurations or adaptations, the use of a relative activation threshold may be more flexible. The threshold can adapt to different operating states or variants without the need to specify specific absolute voltage limits.

The end effector, in particular the control device and its firmware, is parameterizable. For example, the activation and deactivation offsets can be passed as parameters. Due to the parameterability of the offsets, the sensitivity of the activation and deactivation thresholds can be adapted to the specific requirements of the system or application. This provides a high degree of flexibility in adapting to different operating conditions.

Alternatively, absolute activation and deactivation threshold voltages can also be stored in the end effector.

The activation offset can be greater in magnitude than the deactivation offset. The activation threshold voltage can be greater in magnitude than the deactivation threshold voltage.

The following is an example of variable operating conditions of a feedback protection device or a brake chopper:

| | |
|---|---|
| Mean value of the actual voltage | 25.1 V |
| Activation offset | 2.0 V |
| Activation threshold voltage | 27.1 V |
| Deactivation offset | 1.0 V |
| Deactivation threshold voltage | 26.1 V |

In aspects of this disclosure, if an error is triggered and/or an error message is issued if, despite the feedback protection device being activated, the actual voltage does not fall below the deactivation threshold voltage after a maximum active time. In this case, it can be assumed that the feedback protection device is defective, e.g., the protective circuit has switched to the interruption state. The active time begins when the feedback protection device is activated, e.g., when the activation threshold voltage is exceeded, and ends when the feedback protection device is deactivated, e.g., when the deactivation threshold voltage is fallen below.

A computer program comprises instructions which, when executed by a computer, cause the computer to carry out the method described above. The computer program comprises firmware executable on a microcontroller.

Further details and advantageous embodiments of this disclosure can be found in the following description, by which exemplary embodiments of this disclosure are further described and explained.

### BRIEF DESCRIPTION OF THE DRAWINGS

Further advantages and aspects of this disclosure emerge from the claims and from the following description of exemplary embodiments of this disclosure, which are explained below with reference to the figures. Identical and functionally corresponding elements are provided with identical reference signs. In the drawings:

FIG. 1 is a block diagram of an end effector connected to an energy source;

FIG. 2 is a block diagram of a feedback protection device; and

FIG. 3 is a diagram of a voltage curve of an actual voltage, the mean value and the threshold voltages.

### DETAILED DESCRIPTION

Conventional end effectors that include electric drives can encounter damaging voltage spikes during braking, as the electric motor acts as a generator and feeds energy back into the power system. This feedback voltage can disrupt or destroy control electronics or upstream power supplies. External brake choppers or fuses are often required to mitigate this, adding complexity and limiting integration.

As a technical solution, this disclosure provides an end effector with an integrated feedback protection device configured to detect overvoltage conditions, selectively dissipate regenerative braking energy as heat, and operate without reliance on external energy storage or fusing. The control device, which can include a microcontroller and firmware, manages this protection in real time based on measured voltage conditions and drive state (motor or generator mode). This improves operational reliability, integration compactness, and safety across diverse power supply configurations.

Unless otherwise indicated, all terms used in this disclosure are intended to have their ordinary and customary meaning as understood by a person of ordinary skill in the art. The following definitions are provided to clarify the meaning of certain terms as used herein and are not intended to limit the scope of the disclosure or the appended claims. In the event of a conflict between a definition provided herein and the ordinary meaning of a term, the definition provided herein shall control.

As used herein, a “motor operating state” is understood to mean that the electric drive is used to drive the at least one effector element. In this state, the electric drive is supplied with electrical energy by an energy source, in particular a power supply unit, with the energy being conducted from the energy source to the electric drive.

As used herein, a “generator operating state” is understood to mean that during braking, kinetic energy is converted into electrical energy by means of the electric drive, which is then fed back to the energy source.

As used herein, a “controller cascade” is an arrangement of a plurality of control loops connected in series. Each control loop in the controller cascade has its own controlled variable and its own controller.

As used herein, a “feedback voltage” refers to a voltage induced in the supply line or drive circuit as a result of regenerative behavior during braking of the electric drive, such as when the motor acts as a generator. It does not refer to control signal feedback or sensed data signals.

As used herein, an “activation threshold voltage” refers to a voltage level above which the feedback protection device is activated to dissipate braking energy.

As used herein, a “deactivation threshold voltage” refers to a voltage level below which the feedback protection device is deactivated to avoid conflict with upstream regulation.

As used herein, a “feedback protection device” refers to a device integrated within the end effector that is configured to dissipate braking energy, typically as heat, to prevent voltage spikes from damaging internal or external electronics. The device may include load resistors, switches, and control logic.

As used herein, an “end effector” refers to a tool mounted on a handling or robotic apparatus, such as a gripper, manipulator, or other actuator, configured to interact with an object. In the context of this disclosure, the end effector comprises an electric drive and control electronics housed in a compact form factor.

As used herein, a “supply line” refers to an electrical connection configured to transmit power from an external energy source to the electric drive of the end effector.

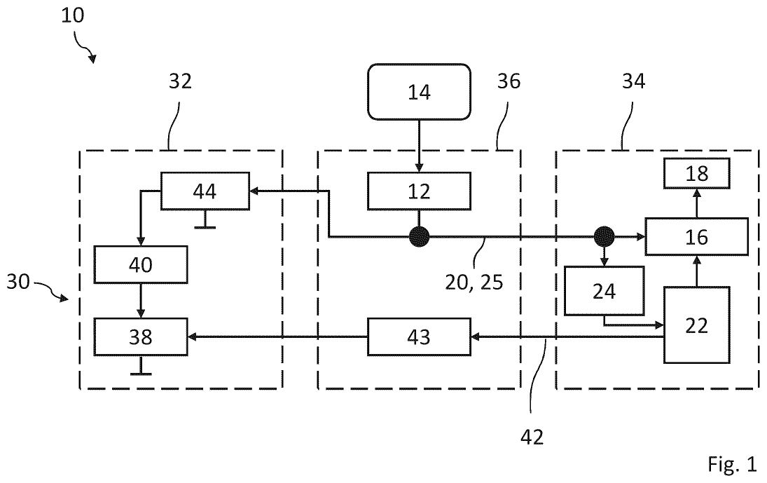

FIG. 1 is a block diagram of an end effector 10, in particular a gripper. The end effector 10 has a main housing (not shown). In the main housing, the end effector has an electrical interface 12 for connection to an external energy source 14. Furthermore, the end effector 10 has an electric drive 16 arranged in the main housing for driving at least one effector element 18. The electric drive 16 is electrically connected to the electrical interface 12 via a supply line 20.

The energy source 14 supplies the electric drive 16 with energy, in particular a motor voltage, preferably of 24 V, via the electrical interface 12 and the supply line 20. The end effector 10 has a control device 22 for controlling the electric drive 16. The control device 22 preferably has firmware.

The electric drive 16 can be designed, for example, as an external rotor motor. During braking of the end effector, in particular the effector element, the motor acts as a generator rather than a drive. The rotor induces a feedback voltage in the stator windings, which can be damaging to the power and control electronics as well as the external energy source 14 and can lead to failures.

A voltage measuring device 24 for measuring an actual voltage 25 is provided on the supply line 20.

The feedback voltage can affect the external energy source 14 via the supply line 20. Therefore, the end effector 10 has a feedback protection device 30. The use of a feedback protection device 30 prevents excessive supply voltage by ensuring that the braking energy is dissipated in a controlled manner. This protects the electronic components and the customer's power supply unit from damage caused by excessive voltages or currents. If the supply voltage is excessive, the applied voltage exceeds specified operating values of the connected electronic components, in particular the power supply unit, which can lead to damage to the connected electronic components, in particular the power supply unit. Without the feedback protection device 30, the end effector can no longer be operated reliably. The effect of excessive supply voltage is amplified when operating a plurality of end effectors on one power supply unit.

The feedback protection device 30 is arranged on a first circuit board 32, in particular a brake chopper board. The first circuit board 32 is preferably formed separately from a second circuit board 34, in particular a main circuit board. The control device 22 and/or the voltage measuring device 24 are preferably arranged on the second circuit board 34. Furthermore, a separate third circuit board 36, in particular a connection board, can be provided, on which the electrical interface 12 is located.

The feedback protection device 30 has a switch 38 and at least one load resistor 40 for converting electrical energy into thermal energy. The switch 38 is designed as a field-effect transistor. The switch 38 can be switched between an activation state and a deactivation state by means of the control device 22.

The feedback protection device 30 is connected to the supply line 20, with the load resistors 40 electrically connected in parallel with the supply line 20 or the electric drive 16.

In the deactivation state, the switch 38 is open, so that no current flows through the load resistors 40. This corresponds to the operation of the motor as a drive. During sharp braking, the actual voltage 25 in the supply line 20 increases. The control device 22 detects the generator operation of the electric drive 16 as well as the increase in the actual voltage 25 and closes the switch 38. In the activation state, current flows to the load resistors 40, so that the braking energy introduced into the end effector by braking is converted into thermal energy. For this purpose, the control device 22 is connected to the switch 38 via a switching line 42. The switching line 42 is preferably designed such that the control device 22 and the switch 38 are galvanically isolated. For galvanic isolation, a means 43 is provided, which can preferably be arranged on the third circuit board 36.

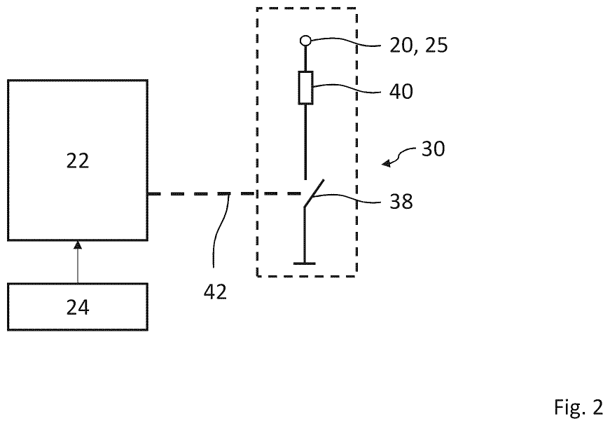

The control device 22, in particular the firmware, receives the voltage signal from the voltage measuring device 24 via the actual voltage 25 applied to the supply line 20, as shown in FIG. 2. The control device 22 then determines, depending on the actual voltage 25, whether the feedback protection device 30 should be activated or deactivated. Depending on the conditions, the control device 22 sends a switching signal via the switching line 42, thereby opening (deactivation state) or closing (activation state) the switch 38.

In the activation state, a current flows through the load resistors 40, converting the electrical energy into thermal energy. Therefore, a significant temperature increase can occur on the first circuit board 32. In order to prevent excessive electrical energy from being converted into thermal energy at the load resistors, an upstream temperature-dependent protective circuit 44 (overtemperature shutdown) is provided. The protective circuit 44 is preferably designed such that it interrupts the electrical connection between the supply line 20 and the load resistors 40 when a threshold temperature is reached. Alternatively or additionally, the protective circuit 44 can also be designed to be voltage-and/or current-dependent and interrupt the electrical connection when a threshold voltage and/or a threshold current is reached.

The control device 22 is preferably designed such that an actual voltage 25 applied to the supply line 20 is first measured. Furthermore, the control device 22 determines whether the end effector 10 is in the motor operating state or in the generator operating state. Furthermore, the control device 22 determines a mean value 46 of the actual voltage 25 by filtering the actual voltage 25 by means of an IIR filter.

In addition, the control device 22 determines an activation threshold voltage 48 and a deactivation threshold voltage 50. The activation threshold voltage 48 represents a permissible voltage level of the end effector 10. The threshold voltages 48, 50 are determined by adding an activation offset 52 and a deactivation offset 54 to the mean value 46. The deactivation offset 54 is selected such that the feedback protection device 30 does not compete with the voltage regulation of a power supply unit. The activation offset 52 can be, for example, 2 V, and the deactivation offset 54 can be 1 V. With a mean value 46 of 24 V, there is an activation threshold voltage 48 of 26 V and a deactivation threshold voltage 50 of 25 V.

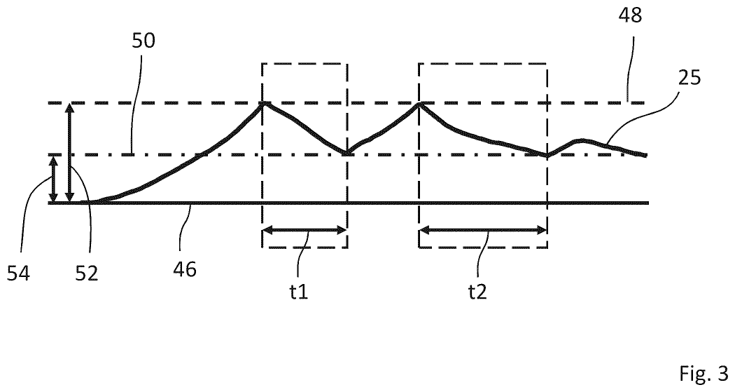

If, according to FIG. 3, the actual voltage 25 exceeds the activation threshold voltage 48 and the end effector is in the generator operating state, the control device 22 sends a switching signal to the switch 38 via the switching line 42, which then closes and activates the feedback protection device 30. Consequently, the braking energy is converted into thermal energy by the load resistors 40. The activation of the feedback protection device 30 is shown in FIG. 3 by the dashed regions. Accordingly, FIG. 3 shows a first activation phase with a first activation time t1 and a second activation phase with a second activation time t2.

If, as shown in FIG. 3, the actual voltage 25 falls below the deactivation threshold voltage 50 and/or the end effector is in the motor operating state, the control device 22 sends a switching signal to the switch 38 via the switching line 42, which then opens and deactivates the feedback protection device 30.

This can lead to the feedback protection device 30 being activated and deactivated multiple times during braking. The excess electrical energy is dissipated in the form of pulses via the load resistors 40. The feedback protection device 30 is preferably switched periodically, so that the excess braking energy is periodically converted into thermal energy by the load resistors 40.

Furthermore, the control device 22 records the active time of the feedback protection device 30. If the actual voltage has not reached or fallen below the deactivation threshold voltage after a maximum active time of 1 s, in particular 500 ms, preferably 300 ms, an error is triggered and/or an error message is issued. It can therefore be assumed that the feedback protection device 30 is defective, e.g. the protective circuit 44 has blown. In this case, a worker should acknowledge the error and take appropriate action.

The integrated feedback protection system described herein offers multiple technical advantages. By embedding the feedback protection device within the end effector and controlling it via a dedicated control device, the system enables precise, real-time response to braking events without the need for external dissipation circuitry or energy storage components. This reduces system complexity and cost while improving safety and reliability. The use of adaptive threshold logic, based on filtered voltage measurements and operating state detection, ensures robust protection across a range of power supply conditions and braking profiles. Furthermore, modular circuit board layout (such as separating heat-generating components from control logic) enhances thermal and electromagnetic compatibility. The parameterizable firmware allows flexible deployment across various robotic applications without requiring hardware changes.

To the extent not already described, the different features and structures of the various embodiments can be used in combination, or in substitution with each other as desired. That one feature is not illustrated in all of the embodiments is not meant to be construed that it cannot be so illustrated, but is done for brevity of description. Thus, the various features of the different embodiments can be mixed and matched as desired to form new embodiments, whether or not the new embodiments are expressly described. All combinations or permutations of features described herein are covered by this disclosure.

Persons skilled in the art will understand that the structures and methods specifically described herein and shown in the accompanying figures are non-limiting exemplary aspects, and that the description, disclosure, and figures should be construed merely as exemplary of aspects. It is to be understood, therefore, that the present disclosure is not limited to the precise aspects described, and that various other changes and modifications can be effected by one skilled in the art without departing from the scope or spirit of the disclosure.

Additionally, the elements and features shown or described in connection with certain aspects can be combined with the elements and features of certain other aspects without departing from the scope of the present disclosure, and that such modifications and variations are also included within the scope of the present disclosure. Accordingly, the subject matter of the present disclosure is not limited by what has been particularly shown and described.

What is claimed:

1. An end effector for arrangement on a handling apparatus, the end effector comprising:
at least one effector element movable by means of an electric drive,
a feedback protection device integrated in the end effector for receiving and/or converting a feedback voltage during braking of the electric drive, and
a control device for controlling the feedback protection device, which is configured to control the feedback protection device based of an average value of a current voltage and an activation limit voltage and/or deactivation limit voltage, the activation limit voltage and/or the deactivation limit voltage being determined from the current voltage and an activation offset and/or a deactivation offset.

2. The end effector in accordance with claim 1, wherein the feedback protection device comprises at least one load resistor for converting a feedback voltage into heat.

3. The end effector in accordance with claim 1, wherein the feedback protection device comprises a switch for activating and deactivating the feedback protection device.

4. The end effector in accordance with claim 1, wherein the end effector has an electrical interface for connection to an electrical energy source for supplying energy to the electric drive, and wherein the feedback protection device is connected to a supply line that electrically connects the electrical interface and the electric drive.

5. The end effector in accordance with claim 2, wherein the feedback protection device is designed such that the switch, in an activation state, electrically connects the at least one load resistor to the supply line and/or, in a deactivation state, electrically disconnects the at least one load resistor from the supply line.

6. The end effector in accordance with claim 4, wherein the end effector has a voltage measuring device for measuring a first variable which characterizes an actual voltage applied to the supply line.

7. The end effector in accordance with claim 1, wherein the feedback protection device, in particular the at least one load resistor and/or the switch, is arranged on a first circuit board.

8. The end effector in accordance with claim 1, wherein the control device is configured to control the electric drive and to activate and deactivate the feedback protection device.

9. The end effector in accordance with claim 1, wherein the control device is arranged on a second circuit board.

10. The end effector in accordance with claim 4, wherein the control device is configured such that it activates or deactivates the feedback protection device depending on an actual voltage applied to the supply line and/or an operating state of the end effector, in particular a motor operating state and a generator operating state.

11. The end effector in accordance with claim 10, wherein the control device is configured to activate the feedback protection device when an actual voltage applied to the supply line exceeds an activation threshold voltage and in particular when the end effector is in a generator operating state, and/or to deactivate the feedback protection device when an actual voltage applied to the supply line falls below a deactivation threshold voltage and in particular when the end effector is in a motor operating state.

12. The end effector in accordance with claim 1, wherein the feedback protection device comprises a temperature-dependent protection circuit which is designed such that it can change into an interruption state.

13. A method for operating an end effector, comprising the following steps:
a) measuring an actual voltage applied to a supply line of the end effector,
b) if the actual voltage exceeds an activation threshold voltage, activating a feedback protection device integrated in the end effector, wherein the activation limit voltage is determined from the actual voltage and an activation offset, and/or
c) if the actual voltage falls below a deactivation threshold voltage, deactivating the feedback protection device integrated in the end effector.

14. The method in accordance with claim 13, wherein the method comprises the following step before step b):
a1) detecting an operating state of the end effector, in particular a generator operating state or a motor operating state.

15. The method in accordance with claim 13, wherein the feedback protection device in accordance with step b) is activated only when the actual voltage exceeds the activation threshold voltage and when the end effector is in a generator operating state.

16. The method in accordance with claim 13, wherein the feedback protection device in accordance with step c) is deactivated only when the actual voltage falls below a deactivation threshold voltage and/or if the end effector is in a motor operating state.

17. The method in accordance with claim 13, wherein the measured actual voltage is filtered to determine a mean value of the actual voltage, in particular by means of an infinite impulse response filter.

18. The method in accordance with claim 17, wherein the activation threshold voltage is determined by adding an activation offset to the mean value.

19. The method in accordance with claim 17, wherein the deactivation threshold voltage is determined by adding a deactivation offset to the mean value.

20. The method in accordance with claim 13, wherein an error is triggered and/or an error message is issued if, with the feedback protection device activated, the actual voltage does not fall below the deactivation threshold voltage after a maximum active time.

21. A computer program comprising instructions which, when the computer program is executed by a computer, cause the computer to carry out the method in accordance with claim 13, wherein the computer program comprises firmware executable on a microcontroller.
